(19) United States
(12) Patent Application Publication
(10) Pub. No.: US 2018/0033768 A1
(43) Pub. Date: Feb. 1, 2018

(54) Flat panel display formed by self aligned assembly

(71) Applicants: Ananda H. Kumar, Fremont, CA (US); Srinivas H. Kumar, Fremont, CA (US); Tue Nguyen, Fremont, CA (US)

(72) Inventors: Ananda H. Kumar, Fremont, CA (US); Srinivas H. Kumar, Fremont, CA (US); Tue Nguyen, Fremont, CA (US)

(21) Appl. No.: 15/660,922

(22) Filed: Jul. 26, 2017

Related U.S. Application Data
(60) Provisional application No. 62/367,092, filed on Jul. 26, 2016.

(51) Int. Cl. H01L 23/00; H01L 33/62; H01L 27/15; H01L 33/08; H01L 27/32; G09G 3/32; H01L 33/20

(52) U.S. Cl. CPC H01L 24/97; G09G 3/32; H01L 33/62; H01L 33/20; H01L 33/08; H01L 24/75; H01L 27/326; H01L 27/15; G09G 2300/0452

(57) ABSTRACT

An LED display can be fabricated by assembling micro LED chips on a backplane substrate. The micro LED chips can be assembled using a flip chip process, achieving self alignment caused by the solder reflow.

The present invention claims priority from U.S. Provisional Patent Application No. 62/367,092, entitle “Self-Aligned Assembly Of Large Arrays Of Micro-components, such as Silicon based pixel circuits, or Micro-LEDs Onto A System Board”, filed on Jul. 26, 2017, which is incorporated herein by reference.

### BACKGROUND

Flat panel displays (FPD), which include liquid crystal displays (LCD), plasma display panels (PDP), electrophoretic display (EPD), organic light emitting diode (OLED) displays, and light emitting diode (LED) displays, can be used in many electronic devices such as mobile phones, tablets, laptop computers, monitors and televisions.

Pixels of the flat panel displays are arranged in a matrix form and controlled by an array of driver circuits, for example, to provide selections of on or off pixels. The driver circuits, which can be implemented with thin film-transistors (TFTs), can be fabricated on a substrate together with interconnect lines for linking the driver circuits and the pixels, called a display backplane, on which the array of pixels can be formed.

The backplane can function as a series of switches, through the driver circuits to the interconnect lines to control a current or voltage applied to each individual pixel. The thin film-transistors can use amorphous silicon (a-Si) channels, low temperature polycrystalline silicon channels, or other channels such as IGZO, all of which typically have a lower mobility than single crystal silicon channels.

### SUMMARY

In some embodiments, methods to form a display can include assembling micro components on a substrate using solder bumps and bond pads connectivity. LED displays can also be formed with micro LED chips, assembling on a backplane.

The backplane can also be fabricated by the assembling process with micro driver chips.

### BRIEF DESCRIPTION OF THE DRAWINGS

FIGS. 1A-1F illustrate a process of assembling micro components on a substrate according to some embodiments.

FIG. 2 illustrates a flow chart for an assembling process according to some embodiments.

FIG. 3 illustrates flow chart for an assembling process of a display according to some embodiments.

FIGS. 4A-4E illustrate a process for making individual micro components according to some embodiments.

FIG. 5 illustrates a flow chart for making micro components according to some embodiments.

FIGS. 6A-6E illustrate a process for forming a LED display according to some embodiments.

FIGS. 7A-7B illustrate configurations of LED display according to some embodiments.

FIG. 8 illustrates a flowchart for forming a LED display according to some embodiments.

FIG. 9 illustrates a flowchart for forming a LED display according to some embodiments.

FIG. 10 illustrates a process for forming a display according to some embodiments.

### DETAILED DESCRIPTION OF THE EMBODIMENTS

In some embodiments, the present invention discloses self assembling of micro components on a substrate using solder bumps. The micro components can be smaller than 100 microns, 50, 20, 10, or 5 microns in a dimension.

In some embodiments, the present invention discloses methods, and backplanes and flat panel displays formed from the methods, to form backplanes and flat panel displays by assembling driver circuit components and/or pixel circuit components on a substrate.

In some embodiments, the substrate can include interconnect lines, e.g., periodic interconnect lines for forming connections to the individual driver circuits and pixel circuits. The substrate can also include bond pads, which are coupled to the interconnect lines.

The driver circuits and the pixel circuits can be fabricated on separate substrates, and diced to form individual driver and pixel components. The driver and pixel components can include bond pads for interconnection. Solder bumps can be formed on the bond pads, to be bonded to bond pads of the interconnect lines in the substrate, such as in a flip chip process.

The assembling of the driver and pixel components on the substrate can be performed by a solder bump process, e.g., placing solder bumps on corresponding bond pads, and heating the assembly to a high temperature to melt the solder bumps, which can form secure bonds with the bond pads. The molten solder bumps can pull the components into perfect alignment with the bond pads, e.g., with the substrate, providing a flat panel self assembling process.

In some embodiments, the present invention discloses an assembly process of a large array of similar devices or circuits, e.g., the driver circuits and the pixel circuits. These arrays can be small micro components, e.g., if micron size such as 5 microns to 100 microns, such as small silicon chips consisting of a few transistors and capacitors making up switching circuits, in the case of an LCD display, or making up switching and driver circuits, in the case of an AMOLED or LED display. The micro component may consist of several such adjacent driver and switching circuits of the display, which can be called driver chips, e.g., driver circuit components fabricated and packaged into semiconductor chips. The micro component may consist of several pixel circuits of the display, which can be called pixel chips, e.g., pixel circuit components fabricated and packaged into semiconductor chips. The display backplane can include a very large number such repeating units, or driver chips, interconnected to form a display backplane. The display backplane can include pixel chips interconnected with the driver chips.

In some embodiments, the present invention discloses driver circuits on single crystal silicon substrate, which can possesses high performance, such as high mobility, as compared to thin film transistors such as a-Si, LTPS, and IGZO. The thin film transistors have performance limitations when compared to devices made in single crystal silicon wafers.

In some embodiments, the driver circuits and the LED circuits (e.g., LED pixel) can be fabricated on single crystal silicon substrate in semiconductor wafer fabs, diced them into individual driver and pixel chips, and gang assembled, in some embodiments, on a temporary carrier and join them on to a display substrate such as glass or other material, in a self aligned attachment to form a large pixel array for a display backplane or display.

Even given the advances in automated assembly tools and methods, the task of assembling large number circuits and would be huge, both in terms of defects that could come about in alignment and assembly, and defects in making the electrical contacts needed, and speed of the overall process and reliability of the overall process are affected.

In some embodiments, a number of driver chips and/or pixel chips can be provided with solder terminals. The chips can be placed in approximate alignment on the corresponding bond pads on the display substrate, and reflowing the solder, which when molten pulls these individual chips into perfect alignment to the later, and to each other, due to surface tension forces. A large number of chips, such as chips placed in 1-5 cm square areas, can be assembled at one time.

In some embodiments, the present invention discloses employing a self-alignment characteristic of flip-chip interconnections for assembling precision circuits.

In some embodiments, driver transistors can be formed on a substrate for a backplane. These transistors can be first fabricated on a wafer using very optimal CMOS process in a fab. In the fab, these will necessarily be processed as a regular array next each other for the economic, good process control and for the process flow, such as for economy, and uniformity.

A substrate, such as a glass substrate for an LCD display, or another material substrate for an LED display, can have interconnect lines fabricated thereon. The substrate then can be populated with the driver transistors, to form a backplane. Pixel elements can then be placed on the backplane to form a display.

Each pixel of such a backplane will need two or three of these transistors, in the given pixel area, which is not necessarily next to each other, but in a distributed arrangement.

The chips that are going to be made in the wafer fab are tested on the wafer, diced into individual chips, and assembled onto the corresponding receiving pads in the driver areas (for the driver chips), or in the pixel areas (for the pixel chips). A typical display would have millions of these chips, so such an assembly of individual chips onto a substrate would be prohibitively difficult and expensive.

In some embodiments, hundreds or thousands of these chips can be assembled on the substrate at a same time, in an easy and self-aligned way. In some embodiments, all the chips can be assembled in one furnace operation.

The driver and pixel arrays can be regular repeating units. Thus a manageable size of these driver and pixel chips can be selected. The manageable size can be large enough to minimize the numbers that we need to assemble. The manageable size should not be too large or too heavy to ease the assembling process, such as not to frustrate self-alignment during the solder reflow. The number of such repeats units in one chip could be, say, a thousand pixels in a reasonable sized chip, such as a manageable size of one cm by one cm chip.

The chips can also be provided with suitable tin-based solder bumps on the terminal metallurgy such as Cr—Cu—Ni—Au, commonly used in flip chip assembly. The solder bumps can be performed in the wafer fabrication process.

Corresponding locations with Cr—Cu—Ni—Au solder bumps for the terminals in the receiving circuit on the substrate preserves the lithography accuracy of the locations on the backplane.

In some embodiments, the present invention gathers a number of micro circuits on temporary plates, and then joins the temporary plates with the substrate to populate the entire substrate by traditional pick and place method. Pick and place and alignment method only requires approximate alignment. Then when the solder is reflowed under proper flux and temperature ramping conditions, followed by the removal of the temporary plates holding these micro circuits.

In some embodiments, a large array of micro circuits can be fabricated on a suitable substrate in a lithographically defined total array. The substrate can be diced, e.g., the micro circuits can be singulated into individual circuits. Hundreds or thousands of these individual circuits can be temporary assembled on a donor plate.

The donor plates, which contain the micro circuits, can be assembled on a substrate onto the corresponding receiving pads on the backplane circuitry of the substrate in approximate alignment. The donor plates can be assembled by available pick and place flip assembly tooling.

After multiple donor plates are assembled on the substrate, the entire assembly can be reflowed, e.g., heated, in one furnace operation so that the solder bumps will melt and realign and join very robustly to the corresponding pads on the backplane structure and board. The donor plates can be removed, leaving millions of micro circuits on the substrate, which are assembled in perfect alignment and making very good electrical contact with tin solder. The assembly of any population of micro circuits can be a good robust manufacturing process.

The bonds these transistors make to the corresponding pads will be strong and reliable because they are self-aligned solder attachments which have very good electrical and thermal properties and will make a very strong interconnection between the pad on the board and the transistor terminals.

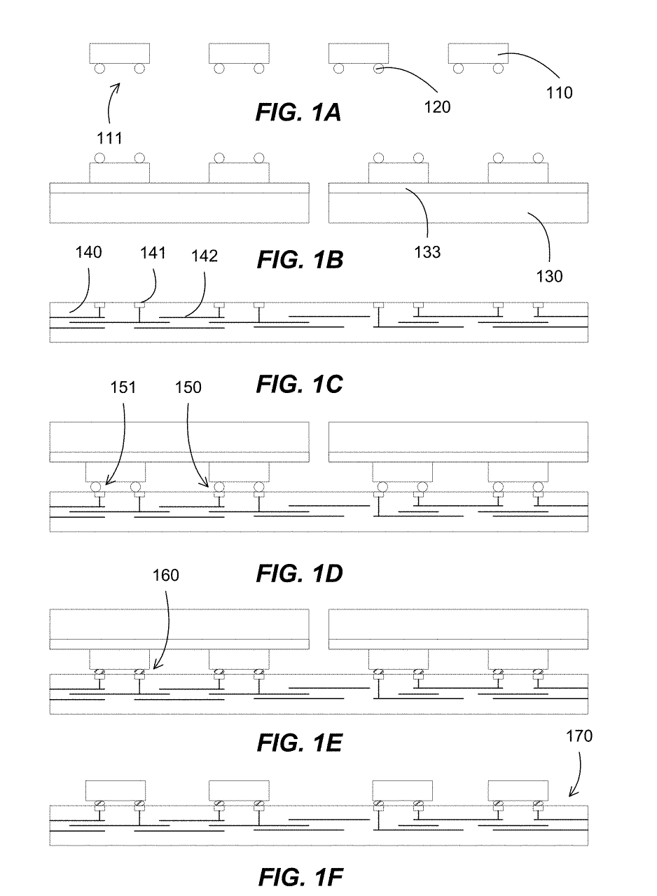

FIGS. 1A-1F illustrate a process of assembling micro components on a substrate according to some embodiments. The micro components can include driver chips, which can be assembled on a substrate having interconnect lines to form a backplane for a flat panel display. The micro components can include pixel chips, which can be assembled on a backplane populated with driver components to form a flat panel display.

In FIG. 1A, micro components 111 can be formed, such as by fabricating on a substrate and singulated into individual micro components. The micro components can include a circuit 110 having solder bumps 120 for interconnection.

In FIG. 1B, the micro components can be assembled on a sacrificial layer 133 on a donor plate 130.

In FIG. 1C, a substrate 140 can be formed. The substrate 140 can be a substrate having arrays of interconnect lines 142 for connecting driver and pixel circuits of a flat panel display. Bond pads 141 can be formed in the substrate 140, and coupled with the interconnect lines. In some embodiments, the substrate can be a backplane with driver circuits.

In FIG. 1D, one or more donor plates can be picked and placed on the substrate, with the solder bumps in approximate alignment with the bond pads. There can be good alignment 150 and there can be misalignment 151 between the solder bumps and the bond pads, due to the approximate alignment of the pick and place process.

In FIG. 1E, the entire assembly can be subjected to a heat treatment process, to reflow the solder bumps for making contact with the bond pads. The reflow process can correct the misalignment, e.g., making the misalignment 151 becoming a good alignment 160.

In FIG. 1F, the donor plates can be removed, for example, by removing the sacrificial layer, to form a complete assembly 170, which includes a substrate populated with multiple micro components in good alignment.

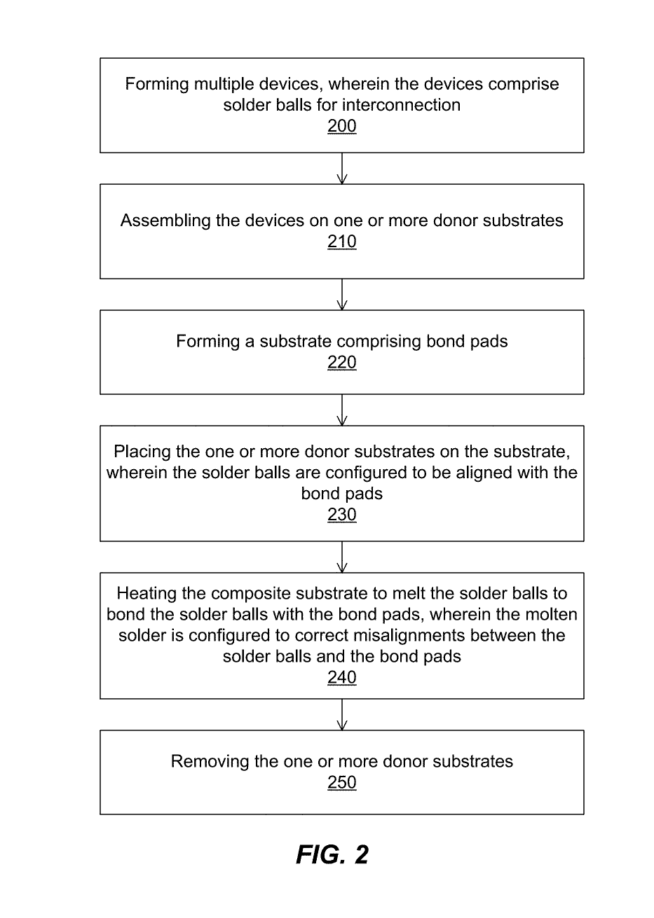

FIG. 2 illustrates a flow chart for an assembling process according to some embodiments. Operation 200 forms multiple devices, wherein the devices comprise solder balls for interconnection. Operation 210 assembles the devices on one or more donor substrates. Operation 220 forms a substrate comprising bond pads. Operation 230 places the one or more donor substrates on the substrate, wherein the solder balls are configured to be aligned with the bond pads. Operation 240 heats the composite substrate to melt the solder balls to bond the solder balls with the bond pads, wherein the molten solder is configured to correct misalignments between the solder balls and the bond pads. Operation 250 removes the one or more donor substrates.

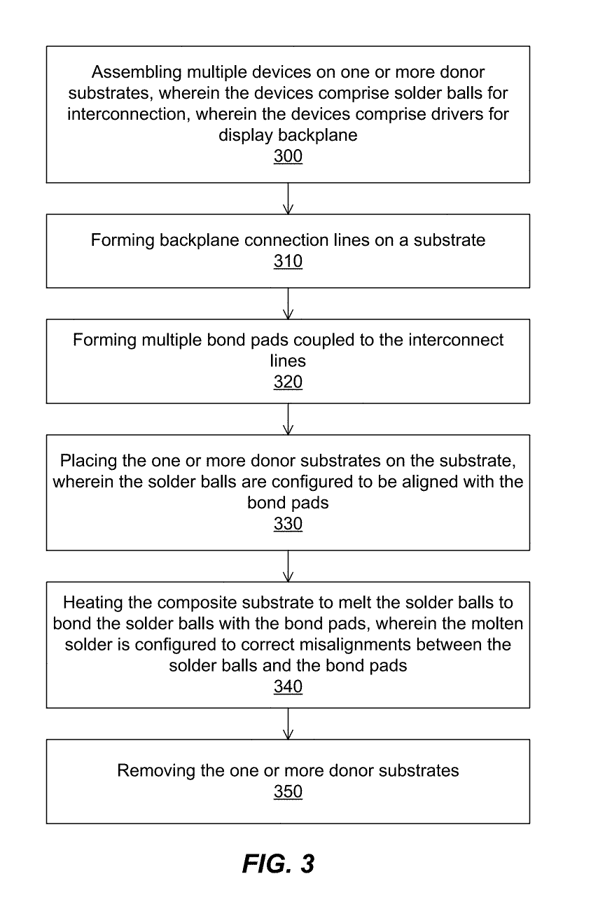

FIG. 3 illustrates flow chart for an assembling process of a display according to some embodiments. Operation 300 assembles multiple devices on one or more donor substrates, wherein the devices comprise solder balls for interconnection, wherein the devices comprise drivers for display backplane. Operation 310 forms backplane connection lines on a substrate. Operation 320 forms multiple bond pads coupled to the interconnect lines. Operation 330 places the one or more donor substrates on the substrate, wherein the solder balls are configured to be aligned with the bond pads. Operation 340 heats the composite substrate to melt the solder balls to bond the solder balls with the bond pads, wherein the molten solder is configured to correct misalignments between the solder balls and the bond pads. Operation 350 removes the one or more donor substrates.

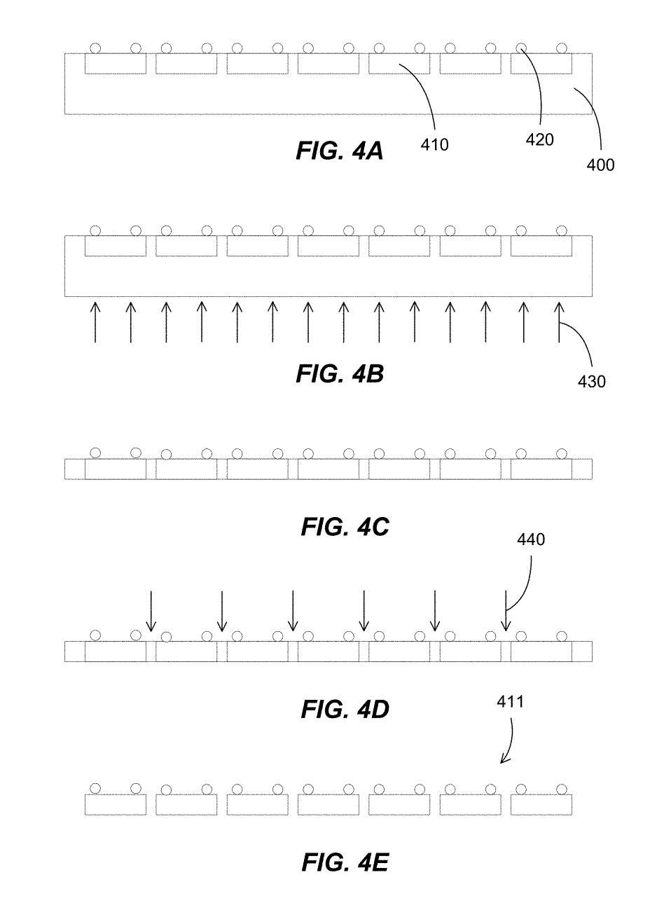

FIGS. 4A-4E illustrate a process for making individual micro components according to some embodiments. FIG. 4A fabricates the micro components 410 on a substrate 400. Solder bumps 420 can be formed on the micro components.

FIG. 4B thins down 430 the substrate. FIG. 4C forms a thinned substrate. FIG. 4D singulates 440 the substrate. FIG. 4E forms individual micro components 411.

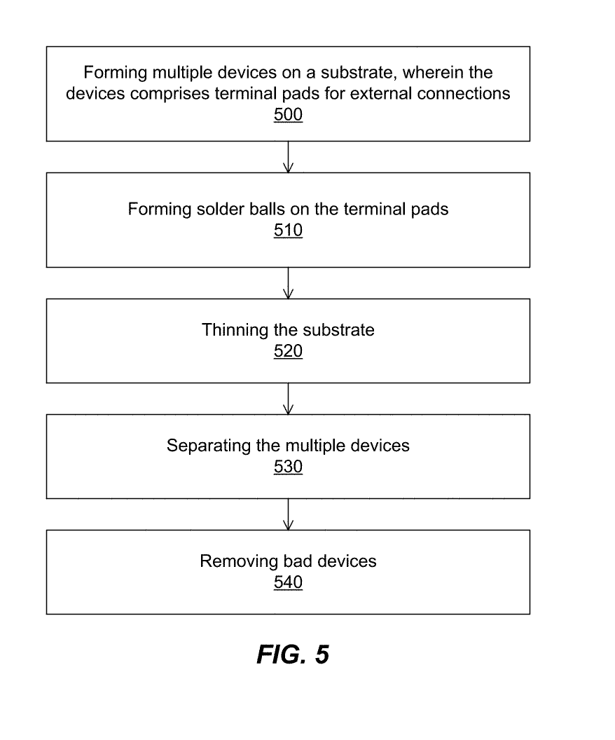

FIG. 5 illustrates a flow chart for making micro components according to some embodiments. Operation 500 forms multiple devices on a substrate, wherein the devices comprises terminal pads for external connections. Operation 510 forms solder balls on the terminal pads. Operation 520 thins the substrate. Operation 530 separates the multiple devices. Operation 540 removes bad devices, e.g., after testing the devices.

In some embodiments, the present invention discloses forming an LED display by assembling micro LED components on a backplane. The backplane can be formed by assembling micro driver components on a substrate having interconnect lines.

The micro LED devices can be made on a sapphire wafer in a regular array on a single wafer. Thousands of these can be made on a single wafer. The individual LED chips on the wafer are tested and marked for goodness, diced, and sorted with only the good ones picked. These then need to be assembled onto to the backplane substrate in the pixel areas, in a distributed way, not necessarily next to each other.

After the dicing, the individual LED chips can be assembled onto a temporary carrier or plate which can be made of display glass or other material, as if to form a virtual backplane array, and stuck to it with flux dots deposited by screen or nozzle printing.

The LED chips are also assembled in an array to replicate the array of the pads on the backplane circuit in the glass. So the glass is the ultimate substrate on which these have to be assembled to form a Smartphone backplane.

The flux-assembled LED array is then ‘diced’ into convenient sized pixel chips. Let us say you have assembled say 1000 of these backplane chips each containing 100 pixels onto this backplane glass, and held there by solder flux.

When we melt the solder by heating to 400 degrees C. in the presence of a suitable flux to melt the solder. When the solder melts it's very nicely wets, which means it attaches onto the terminal in a self-aligned way, correcting any misalignments in placement and cooling, one achieves a solder interconnection that is strong, robust and electrical interconnections between the chip terminals against the glass backplane.

After the reflow we will remove the temporary carrier and the other temporary scaffolding material that was holding these chips together by easy means because we have deliberately chosen materials that make these processes easy.

Once the temporary substrate is removed, we are left with an array of millions of these transistors joined very robustly to this backplane in a very robust electrically and physically robust and metallurgical sound interconnection in a self aligned way as if they were all assembled in one batch, far better than if they are assembled one at a time.

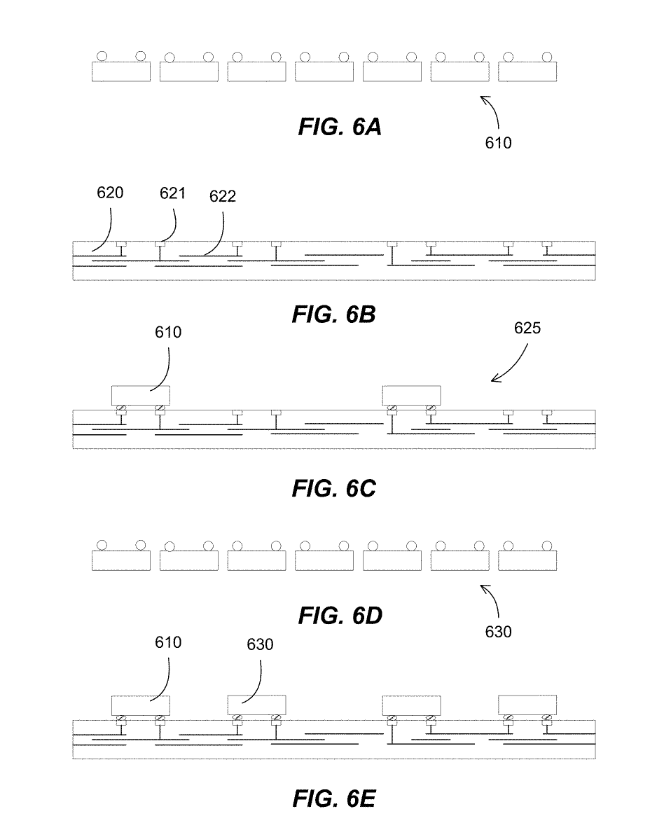

FIGS. 6A-6E illustrate a process for forming a LED display according to some embodiments. In FIG. 6A, individual micro components 610 of driver circuits for a LED display can be formed with solder bumps. For example, the micro components 610 can be fabricated on a single silicon substrate, tested for good dies, and singulated into individual driver components. Only the good dies are kept.

FIG. 6B shows a substrate 620 with interconnect lines 622 and bond pads 621 coupled to the interconnect lines. The interconnect lines can be repeat select Vselect lines, power Vdd lines, and data Vdata lines.

FIG. 6C shows the micro driver chips 610 assembled on the substrate 620. The assembling can include forming donor plates of the micro driver chips, and then bonding the donor plates with the substrate. The donor plates can be removed, to form backplane 625.

FIG. 6D shows micro components 630 of LED circuits, e.g., LED chips, with solder bumps. FIG. 6E shows the micro LED chips 630 assembled on the backplane 625. The assembling can include forming donor plates of the micro LED chips, and then bonding the donor plates with the substrate. The donor plates can be removed.

Two separate heating processes can be performed, one after the assembly of the micro driver chips, and one after the assembly micro LED chips. Alternatively, a heating process can be performed after the assembly of the micro driver chips and micro LED chips.

Variations of the process can be used, such as without the assembling of micro LED chips, or the fabrication of the LED display without the assembling of the micro driver chips.

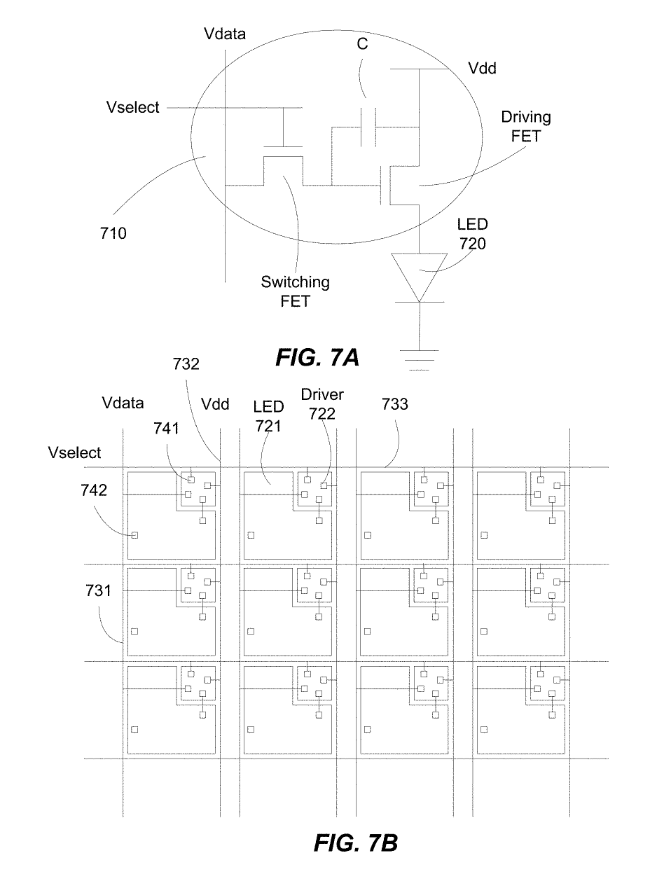

FIGS. 7A-7B illustrate configurations of LED display according to some embodiments. In FIG. 7A, a driver circuit 710 can include a driving FET and a switching FET, together with support components such as a capacitor C. A LED circuit 720 can include a LED device. The driver circuit and the LED circuit can be connected to interconnect lines of Vdata, Vselect, and Vdd.

FIG. 7B shows a plane view of interconnect lines Vdata 731, Vselect 733, and Vdd 732, together with the LED circuits 721 and the driver circuits 722. The LED circuits are connected to the interconnect lines through bondpads 742. The driver circuits are connected to the interconnect lines through bondpads 741.

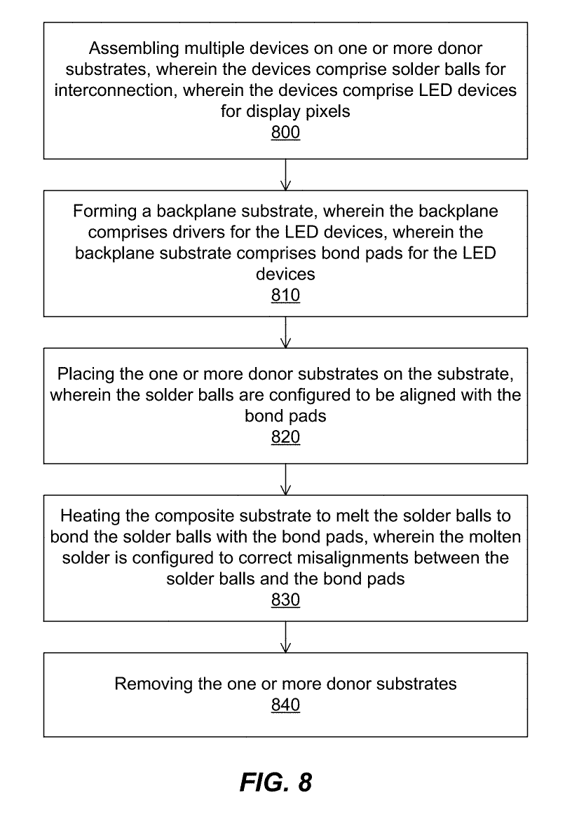

FIG. 8 illustrates a flowchart for forming a LED display according to some embodiments. Operation 800 assembles multiple devices on one or more donor substrates, wherein the devices comprise solder balls for interconnection, wherein the devices comprise LED devices for display pixels. Operation 810 forms a backplane substrate, wherein the backplane comprises drivers for the LED devices, wherein the backplane substrate comprises bond pads for the LED devices. Operation 820 places the one or more donor substrates on the substrate, wherein the solder balls are configured to be aligned with the bond pads. Operation 830 heats the composite substrate to melt the solder balls to bond the solder balls with the bond pads, wherein the molten solder is configured to correct misalignments between the solder balls and the bond pads. Operation 840 removes the one or more donor substrates.

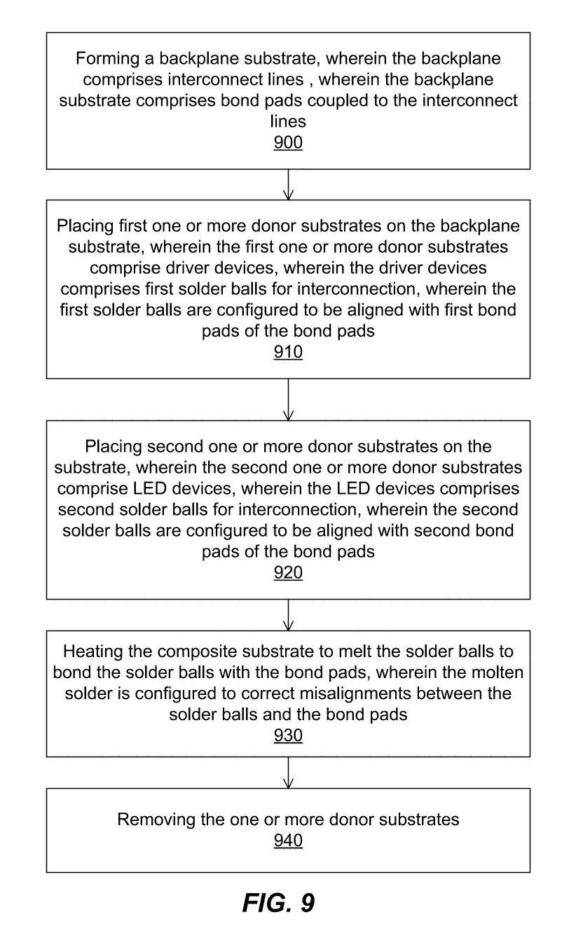

FIG. 9 illustrates a flowchart for forming a LED display according to some embodiments. Operation 900 forms a backplane substrate, wherein the backplane comprises interconnect lines, wherein the backplane substrate comprises bond pads coupled to the interconnect lines. Operation 910 places first one or more donor substrates on the backplane substrate, wherein the first one or more donor substrates comprise driver devices, wherein the driver devices comprises first solder balls for interconnection, wherein the first solder balls are configured to be aligned with first bond pads of the bond pads. Operation 920 places second one or more donor substrates on the substrate, wherein the second one or more donor substrates comprise LED devices, wherein the LED devices comprises second solder balls for interconnection, wherein the second solder balls are configured to be aligned with second bond pads of the bond pads. Operation 930 heats the composite substrate to melt the solder balls to bond the solder balls with the bond pads, wherein the molten solder is configured to correct misalignments between the solder balls and the bond pads. Operation 940 removes the one or more donor substrates.

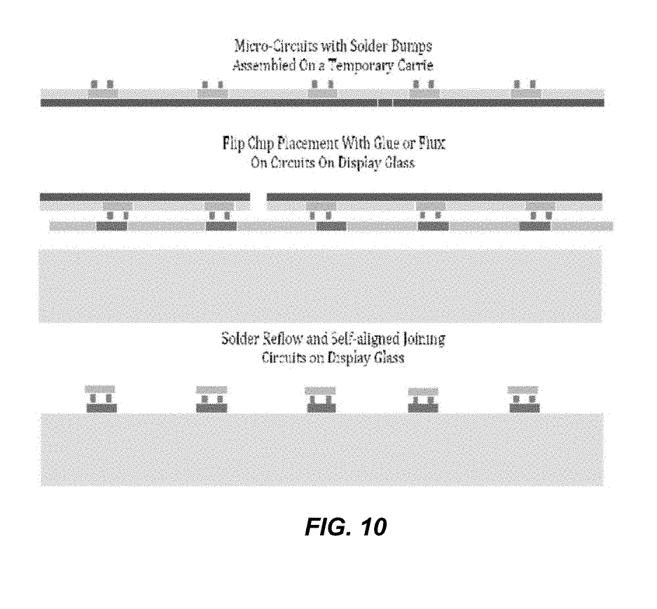

FIG. 10 illustrates a process for forming a display according to some embodiments. Micro circuits with solder bumps can be assembled on a temporary carrier. Flip chip placement with glue or flus on circuits on a display substrate. After heating, the solder reflows and self aligned, joining the micro circuits with the circuits on the display substrate.

What is claimed is:

1. A method to form a backplane for a flat panel display, the method comprising
forming interconnect lines on a substrate, wherein the interconnect lines are configured to control pixels of the flat panel display;
forming bond pads on the substrate, wherein the bond pads are coupled to the interconnect lines;
forming individual micro driver chips, wherein the driver chips comprise circuits for driving the pixels of the flat panel display, wherein the driver chips comprise solder bumps for interconnection;
bonding the individual micro driver chips onto temporary carriers;
placing the temporary carriers onto the substrate with the solder bumps approximately aligned with the bond pads;
reflowing the solder to form bonds between the solder bump and the bond pads;
removing the temporary carriers from the driver chips.

2. A method as in claim 1
wherein the interconnect lines comprise a first set of parallel lines crossing but not connecting a second set of lines.

3. A method as in claim 1
wherein the bond pads are configured to couple the driver chips to the interconnect lines.

4. A method as in claim 1
wherein a size of the driver chips is less than 50 microns.

5. A method as in claim 1
wherein a size of the driver chips is less than 20 microns.

6. A method as in claim 1
wherein the driver chips comprise terminal pads for bonding with the solder bumps.

7. A method as in claim 1
wherein the driver chips are bonded onto the temporary carriers through a sacrificial layer,
wherein the sacrificial layer is removed for removing the temporary carrier from the driver chips.

8. A method as in claim 1
wherein the solder reflow is performed by a heating process.

9. A method as in claim 1
wherein the solder reflow corrects misalignments between the solder bumps and the bond pads.

10. A method to form an LED flat panel display, the method comprising
forming a backplane for an LED display, wherein the backplane comprises interconnect lines on a substrate, wherein the interconnect lines are configured to control pixels of the LED flat panel display, wherein the backplane comprises bond pads coupled to the interconnect lines;
forming individual micro LED chips, wherein the LED chips comprise circuits for functioning as the pixels of the flat panel display, wherein the LED chips comprise solder bumps for interconnection;
bonding the individual micro LED chips onto temporary carriers;
placing the temporary carriers onto the backplane with the solder bumps approximately aligned with the bond pads;
reflowing the solder to form bonds between the solder bump and the bond pads;
removing the temporary carriers from the LED chips.

11. A method as in claim 10
wherein the backplane is formed by assembling of micro driver chips onto a substrate through solder reflowing.

12. A method as in claim 10
wherein a size of the LED chips is less than 50 microns.

13. A method as in claim 10
wherein a size of the LED chips is less than 20 microns.

14. A method as in claim 10
wherein the LED chips are fabricated on a sapphire substrate.

15. A method as in claim 10
wherein the LED chips are bonded onto the temporary carriers through a sacrificial layer,
wherein the sacrificial layer is removed for removing the temporary carrier from the LED chips.

16. A method as in claim 10
wherein the solder reflow corrects misalignments between the solder bumps and the bond pads.

17. An LED flat panel display comprising
a backplane, wherein the backplane comprises interconnect lines on a substrate, wherein the interconnect lines are configured to control pixels of the LED flat panel display, wherein the backplane comprises bond pads coupled to the interconnect lines;
individual micro LED chips, wherein the LED chips comprise circuits for functioning as the pixels of the flat panel display, wherein the LED chips comprise solder bumps for interconnection,
wherein the LED chips are coupled to the backplane through reflow bonds between the solder bumps and the bond pads.

18. A display as in claim 17
wherein the backplane comprises micro driver chips coupled to the interconnect lines through solder reflow bonds between solder bumps of the driver chips and the bond pads coupled to the interconnect lines.

19. A display as in claim 18
wherein a size of the driver chips is less than 20 microns.

20. A display as in claim 17
wherein a size of the LED chips is less than 20 microns.
